(19) United States
(12) Patent Application Publication
(10) Pub. No.: US 2024/0046080 A1
(43) Pub. Date: Feb. 8, 2024

(54) VERTICAL NAND FLASH TYPE SEMICONDUCTOR DEVICE AND METHOD OF OPERATING THE SAME

(71) Applicants: SK hynix Inc., Icheon (KR); SEOUL NATIONAL UNIVERSITY R&DB FOUNDATION, Seoul (KR)

(72) Inventors: Jong Ho Lee, Seoul (KR); Jong Won Back, Seoul (KR)

(21) Appl. No.: 18/327,732

(22) Filed: Jun. 1, 2023

(30) Foreign Application Priority Data
Jul. 28, 2022 (KR) 10-2022-0094253

(51) Int. Cl. G06N 3/063; G11C 11/56; G11C 11/54; G11C 16/04

(52) U.S. Cl. CPC G06N 3/063; G11C 11/5621; G11C 11/5671; G11C 11/54; G11C 16/0483

(57) ABSTRACT

A vertical NAND flash type semiconductor device may include a plurality of cell strings extending vertically, each of the plurality of cell strings including a plurality of cells connected in series vertically. The plurality of cells in each cell strings include a plurality of effective cells for data storage and a plurality of compensation cells for resistance compensation. In each cell string, a change in a string resistance of the cell string that may occur due to a change of resistance states of the plurality of effective cells of that cell string may be controlled by controlling resistance states of the plurality of compensation cells of that cell string according to the resistance states of the plurality of effective cells in that cell string.

### CROSS-REFERENCES TO RELATED APPLICATION

The present application claims, under 35 U.S.C. § 119(a), the benefit of Korean application 10-2022-0094253, filed on Jul. 28, 2022, which is herein incorporated by reference in its entirety.

### BACKGROUND

### 1. Field

The present invention relates to a semiconductor device and an operating method thereof, and more particularly, to a vertically stacked semiconductor device and an operating method thereof.

### 2. Description of the Related Art

A flash memory is a non-volatile data storage device which may electrically erase and rewrite data. Flash memory is classified into NAND flash and NOR flash according to the shape of an internal electronic circuit. In a NAND flash, memory cells may be connected in series and an address line may be installed as a block unit. In the NOR flash, memory cells may be connected in parallel and an address line may be installed as a cell unit. The NAND flash has advantages such as relatively low manufacturing cost, fast write speed, and suitable use for a large capacity. The vertical NAND (V-NAND) flash memory stacks memory cells vertically and uses a charge trap flash architecture. The vertical stacking structure may implement a large data density in a small area.

Meanwhile, recently, as the scaling reduction of transistors has reached its limit, the neuromorphic computing system is attracting a lot of attention as a concept which may overcome the limitations of the existing von Neumann-type computer system. Neuromorphic computing implements artificial intelligence operations by mimicking the human brain in a hardware manner. Neuromorphic computing may imitate the structure of the human brain itself and perform artificial intelligence operations such as computation, inference, and recognition which are remarkably superior to the existing von Neumann-style computing with ultra-low power. As a synapse device applied to a neuromorphic system, resistive random access memory (RRAM) and memristor-based devices have been extensively studied, and metal-oxide-semiconductor field-effect transistor (MOSFET)-based synaptic devices have been also studied. Recently, research to apply a NAND flash structure to a neuromorphic system has been attempted.

In a cell string array of a NAND flash memory, the resistance of the cells changes according to the programmed or erased number of cells connected to one string, and as a result of it, the current/resistance of the cell string changes. This may cause an error in reading memory information. In particular, when trying to use cells in a cell string of a NAND flash memory as a synaptic mimic device, this problem causes a problem of lowering the accuracy of weight summing and consequently lowering accuracy of inference. This problem may be exacerbated as the number of stacked cells increases in a vertical NAND (V-NAND) flash memory.

### SUMMARY OF THE INVENTION

An object of the present invention is to provide a vertical NAND flash type semiconductor device capable of effectively controlling a change in resistance of a cell string according to a change in resistance states of the cells.

In addition, another object of the present invention is to provide a vertical NAND flash type semiconductor device capable of increasing the accuracy of calculation and inference, and improving the performance of a neural network by controlling a change in resistance of a cell string according to a change in resistance states of a plurality of cells connected to the cell string when applying a vertical NAND flash structure to a neuromorphic device/system.

Another object of the present invention is to provide a method of operating the above-described vertical NAND flash type semiconductor device.

The objects to be achieved by the present invention are not limited to the objects mentioned above, and other objects not mentioned will be understood by those skilled in the art from the following description.

According to an embodiment of the present invention, there is provided vertical NAND flash type semiconductor device. The device includes a plurality of cell strings extending vertically, each of the plurality of cell strings includes a plurality of cells connected in series vertically, the plurality of cells in each of the plurality of cell strings include a plurality of effective cells for data storage and a plurality of compensation cells for resistance compensation, and wherein the vertical NAND flash type semiconductor device is configured to control a change in a string resistance of a cell string according to a change of resistance states of the plurality of effective cells of the cell string by controlling resistance states of the plurality of compensation cells according to resistance states of the plurality of effective cells in each of the plurality of cell strings.

Each of the plurality of cells may have a plurality of resistance states, and the plurality of resistance states may include a first resistance state and a second resistance state corresponding to an inverse resistance state of the first resistance state. In each of the plurality of cell strings, a number of effective cells having the first resistance state among the plurality of effective cells and a number of compensation cells having the second resistance state among the plurality of compensation cells may be adjusted to a predetermined ratio.

The predetermined ratio may be, for example, 1:1.

A number of the plurality of compensation cells in each of the plurality of cell strings may be about ⅓ or more of a number of the plurality of effective cells.

A number of the plurality of compensation cells in each of the plurality of cell strings may be the same as a number of the plurality of effective cells.

Each of the plurality of cells may be a binary cell having a first resistance state and a second resistance state.

A number of the plurality of compensation cells in each of the plurality of cell strings may be equal to a number of the plurality of effective cells, and each of the plurality of cells may be a binary cell having a first resistance state and a second resistance state. The vertical NAND flash type semiconductor device may be configured to equalize a number of effective cells having the first resistance state among the plurality of effective cells and a number of compensation cells having the second resistance state among the plurality of compensation cells in each of the plurality of cell strings.

Each of the plurality of cells may be a multi-level cell having three or more resistance states.

A plurality of word lines respectively connected to the plurality of cells, and a plurality of bit lines respectively connected to the plurality of cell strings may be provided, and the vertical NAND flash type semiconductor device may be configured to sum current values measured in at least two bit lines among the plurality of bit lines.

The plurality of effective cells may be synaptic cells mimicking a synapse, and the vertical NAND flash type semiconductor device may be a neuromorphic device.

The vertical NAND flash type semiconductor device may further include at least one switching device connected to each of both ends of each of the plurality of cell strings.

According to another embodiment of the present invention, there is provided a method of operating a vertical NAND flash type semiconductor device, the method comprising preparing a vertical NAND flash type semiconductor device including a plurality of cell strings extending vertically, wherein each of the plurality of cell strings includes a plurality of cells connected in series vertically, the plurality of cells in each of the plurality of cell strings include a plurality of effective cells for data storage and a plurality of compensation cells for resistance compensation; and controlling resistance states of the plurality of compensation cells according to resistance states of the plurality of effective cells in one cell string among the plurality of cell strings, and wherein a change in string resistance according to a change in resistance states of the plurality of effective cells in the cell string is controlled by the controlling the resistance states of the plurality of compensation cells.

Each of the plurality of cells may have a plurality of resistance states, and the plurality of resistance states may include a first resistance state and a second resistance state corresponding to an inverse resistance state of the first resistance state, and wherein the method of operating a vertical NAND flash type semiconductor device may configured to adjust a number of effective cells having the first resistance state among the plurality of effective cells and a number of compensation cells having the second resistance state among the plurality of compensation cells of the cell string to a predetermined ratio in the controlling the resistance states of the plurality of compensation cells.

The predetermined ratio may be, for example, 1:1.

A number of the plurality of compensation cells may be equal to a number of the plurality of effective cells in each of the plurality of cell strings.

A number of the plurality of compensation cells in each of the plurality of cell strings may be equal to a number of the plurality of effective cells, and each of the plurality of cells may be a binary cell having a first resistance state and a second resistance state, and wherein the method of operating a vertical NAND flash type semiconductor device may be configured to equalize a number of effective cells having the first resistance state among the plurality of effective cells and a number of compensation cells having the second resistance state among the plurality of compensation cells of the cell string in the controlling the resistance states of the plurality of compensation cells.

The plurality of effective cells may be synaptic cells mimicking a synapse, and the vertical NAND flash type semiconductor device may be a neuromorphic device.

The vertical NAND flash type semiconductor device may further include at least one switching device connected to each of both ends of each of the plurality of cell strings.

According to embodiments of the present invention, it is possible to implement a vertical NAND flash type semiconductor device capable of effectively controlling a change in resistance of a cell string according to a change in resistance states of the cells. In particular, according to embodiments of the present invention, in applying a vertical NAND flash structure to a neuromorphic device/system, it is possible to implement a vertical NAND flash type semiconductor device capable of increasing the accuracy of calculation and inference, and improving the performance of a neural network by controlling a change in resistance of a cell string according to a change in resistance states of a plurality of cells connected to the cell string.

However, the effects of the present invention are not limited to the above effects, and may be variously expanded without departing from the spirit and scope of the present invention.

### BRIEF DESCRIPTION OF THE DRAWINGS

FIG. 1 is a circuit diagram schematically illustrating a vertical NAND flash type semiconductor device according to an embodiment of the present invention.

FIG. 2 is a circuit diagram illustrating an example case in which the resistance states of the effective cells and the resistance states of the compensation cells in each of the plurality of cell strings are adjusted in a vertical NAND flash type semiconductor device according to an embodiment of the present invention.

FIG. 3 is a graph illustrating problematic string resistance changes according to a change in resistance states of a plurality of cells for data storage in a vertical NAND flash type semiconductor device which does not use a compensation cell.

FIG. 4 is a graph illustrating a threshold voltage change amount (ΔVₜₕ) according to the change of the overdrive voltage (Vₚₐₛₛ−Vₜₕ) used in reading the cell in the measurement of FIG. 3.

FIG. 5 is a graph illustrating a program/erase window of a cell included in the vertical NAND flash type semiconductor device applied to the measurement of FIG. 3.

FIG. 6 is a graph illustrating a change in measurement current after a number of program/erase (P/E) cycles in a vertical NAND flash type semiconductor device according to an embodiment of the present invention and a vertical NAND flash type semiconductor device according to a comparative example.

FIG. 7 is a schematic diagram illustrating a program/erase (P/E) cycle and a current measurement method which may be applied when evaluating the vertical NAND flash type semiconductor device according to the embodiment described with reference to FIG. 6.

FIG. 8 is a diagram illustrating a program/erase (P/E) cycle and a current measurement method which may be applied when evaluating the vertical NAND flash type semiconductor device according to the embodiment described with reference to FIG. 6.

FIG. 9 is a circuit diagram schematically illustrating a neuromorphic device using a vertical NAND flash type semiconductor device.

FIG. 10 is a conceptual diagram illustrating a neural network using a vertical NAND flash type semiconductor device.

### DETAILED DESCRIPTION OF THE INVENTION

Hereinafter, the embodiments of the present invention will be described in detail with reference to the accompanying drawings.

The embodiments of the present invention to be described below are provided to more clearly explain the present invention to those having common knowledge in the related art, and the scope of the present invention is not limited by the following embodiments. The following embodiment may be modified in many different forms.

The terminology used herein is used to describe specific embodiments, and is not used to limit the present invention. As used herein, terms in the singular form may include the plural form unless the context clearly dictates otherwise. Also, as used herein, the terms “comprise” and/or “comprising” specifies presence of the stated shape, step, number, action, member, element and/or group thereof; and does not exclude presence or addition of one or more other shapes, steps, numbers, actions, members, elements, and/or groups thereof. In addition, the term “connection” as used herein is a concept that includes not only that certain members are directly connected, but also a concept that other members are further interposed between the members to be indirectly connected.

In addition, in the present specification, when a member is said to be located “on” another member, this includes not only a case in which a member is in contact with another member but also a case in which another member is present between the two members. As used herein, the term “and/or” includes any one and any combination of one or more of those listed items. In addition, as used herein, terms such as “about”, “substantially”, etc. are used as a range of the numerical value or degree, in consideration of inherent manufacturing and material tolerances, or as a meaning close to the range. Furthermore, accurate or absolute numbers provided to aid the understanding of the present application are used to prevent an infringer from using the disclosed present invention unfairly.

Hereinafter, the embodiments of the present invention will be described in detail with reference to the accompanying drawings. The size or the thickness of the regions or the parts illustrated in the accompanying drawings may be slightly exaggerated for clarity and convenience of description. The same reference numerals refer to the same elements throughout the detailed description.

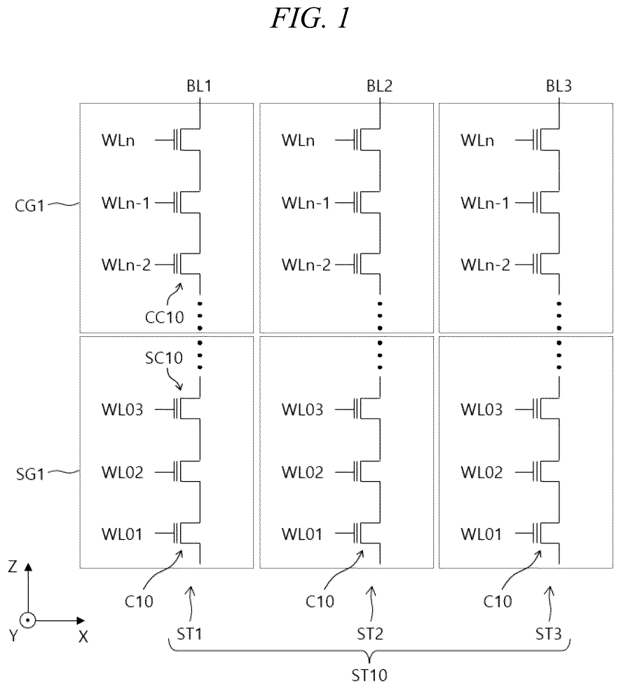

FIG. 1 is a circuit diagram schematically illustrating a vertical NAND flash type semiconductor device according to an embodiment of the present invention.

Referring to FIG. 1, a vertical NAND flash type semiconductor device according to an embodiment of the present invention may include a plurality of cell strings ST10 vertically extended. The plurality of cell strings ST10 may extend in a vertical direction, that is, in a Z-axis direction. Here, for convenience, a case in which the plurality of cell strings ST10 includes three cell strings ST1, ST2, and ST3 is illustrated, but in reality, four or more cell strings may be provided. The plurality of cell strings ST10 may be arranged to form a plurality of columns and a plurality of rows on the XY plane.

Each of the plurality of cell strings ST10 may include a plurality of cells C10 vertically connected in series. The plurality of cells C10 may have a configuration corresponding to a plurality of cells constituting a NAND flash device. Accordingly, it may be said that the plurality of cells C10 have a NAND flash cell structure. Each of the plurality of cells C10 may have a transistor structure. More specifically, each of the plurality of cells C10 may include a channel region, a source, and a drain, and a may include a tunnel insulating layer, a charge storage layer (charge trap layer), and a blocking insulating layer and a gate electrode which are sequentially disposed on the channel region. However, the structure of each cell C10 is not limited to the above description and may be variously changed. A plurality of cells C10 in each cell string ST10 may share one channel layer. The channel layer may extend perpendicular to a substrate, that is, in the Z-axis direction in the drawing. A plurality of cells C10 constituting one cell string ST10 may be formed on the channel layer.

In each of the plurality of cell strings ST10, the plurality of cells C10 may include a plurality of effective cells SC10 for data storage and a plurality of compensation cells CC10 for resistance compensation. The plurality of effective cells SC10 may constitute an effective cell group SG1, and the plurality of compensation cells CC10 may constitute a compensation cell group CG1. In FIG. 1, although a case in which the plurality of effective cells SC10 constitute one effective cell group SG1, the plurality of compensation cells CC10 constitute one compensation cell group CG1, and the compensation cell group CG1 is disposed above the effective cell group SG1 is illustrated, this is an example and may be variously changed depending on the case. For example, in at least one of the plurality of cell strings ST10, the plurality of effective cells SC10 and the plurality of compensation cells CC10 may be mixed and disposed according to a specified rule. Also, at least one of the plurality of cell strings ST10 may be configured to include a plurality of effective cell groups SG1 and/or a plurality of compensation cell groups CG1.

A plurality of word lines WL01 to WLn respectively connected to the plurality of cells C10 may be provided, and a plurality of bit lines BL1 to BL3 connected to each of a plurality of cell strings ST10 may be provided. The plurality of word lines WL01 to WLn may be connected to gate electrodes of the plurality of cells C10, respectively. In a structure in which the plurality of cell strings ST10 are arranged, word lines of the same level may be configured as one word line. For example, the word lines corresponding to WL01 in ST1, ST2, and ST3 may be the same single word line. This may be equally applied to the word line corresponding to WLn.

In embodiments, a first plurality of word lines may be configured as effective word lines and a second plurality of word lines may be configured as compensation word lines, wherein each cell connected to an effective word line is configured as an effective cell and each connected to a compensation word line is configured as a compensation cell. Configuring word lines as effective word lines or compensation word lines may be performed using hardware, using software, or both. For example, in an embodiment, configuring word lines as effective word lines or compensation word lines may be performed by writing parameters to configuration registers of the vertical NAND flash semiconductor device. In another embodiment, configuring word lines as effective word lines or compensation word lines may be performed according to parameters provided to software operating on a device using the vertical NAND flash semiconductor device.

Each of the plurality of bit lines BL1 to BL3 may be connected to a channel layer of each of the cell strings ST10. Here, only three bit lines BL1 to BL3 are illustrated, but in reality, the number of bit lines may be four or more. The bit lines BL1 to BL3 may receive signals independently of each other.

By controlling resistance states of the plurality of compensation cells CC10 according to resistance states of the plurality of effective cells SC10 in each of the plurality of cell strings ST10, the vertical NAND flash type semiconductor device according to the embodiment of the present invention may be configured to control a change in string resistance of a corresponding cell string according to a change in the resistance states of the effective cell SC10. In devices of the related art, the string resistance of the corresponding cell string may be changed according to the resistance state of each of the plurality of effective cells SC10 included in one cell string. But, in embodiments, a change in the string resistance may be suppressed by controlling the resistance states of the plurality of compensation cells CC10 according to the resistance states of the plurality of effective cells SC10. In particular, the string resistance of a cells string when an effective cell SC10 of that cell string is read will change substantially based on the present resistance value of the effective cell SC10 being read, and not substantially change based on the present resistance value of the cells not being read. Accordingly, regardless of how the resistance states of the plurality of effective cells SC10 are changed, for a given resistance value of an effective cell in the string being read, the string resistance of the corresponding cell string may be maintained as constant or substantially constant.

The above-described string resistance may correspond to the resistance of the channel layer of the corresponding cell string. The resistance of the channel layer may be measured as a current through a corresponding bit line. Accordingly, when the string resistance, that is, the channel layer resistance, is changed, a current value measured in a corresponding bit line may be changed. In the embodiment of the present invention, it is possible to suppress a change in the string resistance by controlling the resistance states of the plurality of compensation cells CC10 according to the resistance states of the plurality of effective cells SC10. As a result of it, it is possible to suppress the current change of the corresponding bit line according to the change of the resistance states of the plurality of effective cells SC10.

Each of the plurality of cells C10 may have a plurality of resistance states. The plurality of resistance states may include a first resistance state and a second resistance state corresponding to an inverse resistance state of the first resistance state. The vertical NAND flash type semiconductor device may be configured to adjust a number of effective cells having the first resistance state among the plurality of effective cells SC10 and a number of compensation cells having the second resistance state among the plurality of compensation cells CC10 to a predetermined ratio in each of the plurality of cell strings ST10. The predetermined ratio may be, for example, 1:1. However, in some cases, the predetermined ratio may be 1:2, 1:3, 1:4, or the like. In addition, the vertical NAND flash type semiconductor device may be configured to adjust a number of effective cells having the second resistance state among the plurality of effective cells SC10 and a number of compensation cells having the first resistance state among the plurality of compensation cells CC10 to a predetermined ratio in each of the plurality of cell strings ST10. The predetermined ratio may be, for example, 1:1. However, in some cases, the predetermined ratio may be 1:2, 1:3, 1:4, or the like.

For example, each of the plurality of cells C10 may have a first resistance state in which charges are not charged in the charge storage layer, and a second resistance state in which the charges are charged in the charge storage layer. Here, the first resistance state may be referred to as an erased state, and the second resistance state may be referred to as a programmed state. The second resistance state may be referred to as an inverse resistance state of the first resistance state. The first resistance state may correspond to data ‘1’ and the second resistance state may correspond to data ‘0’, or vice versa. The vertical NAND flash type semiconductor device may be configured to adjust a number of effective cells having the first resistance state (i.e., an erased state) among the plurality of effective cells SC10 and a number of compensation cells having the second resistance state (i.e., programmed state) among the plurality of compensation cells CC10 to a predetermined ratio in each of the plurality of cell strings ST10. In addition, the vertical NAND flash type semiconductor device may be configured to adjust a number of effective cells having the second resistance state (i.e., programmed state) among the plurality of effective cells SC10 and a number of compensation cells having the first resistance state (i.e., an erased state) among the plurality of compensation cells CC10 to a predetermined ratio in each of the plurality of cell strings ST10.

According to an embodiment, in each of the plurality of cell strings ST10, the number of the plurality of compensation cells CC10 may be the same as the number of the plurality of effective cells SC10. In this case, each of the plurality of cells C10 may be a binary cell having a first resistance state and a second resistance state. The first resistance state may be an erased state, and the second resistance state may be a programmed state. The vertical NAND flash type semiconductor device may be configured to adjust (i.e., equalize) the number of effective cells having the first resistance state among the plurality of effective cells SC10 and the number of compensation cells having the second resistance state among the plurality of compensation cells CC10 to the same number in each of the plurality of cell strings ST10. In addition, in the vertical NAND flash type semiconductor device may be configured to adjust (i.e., equalize) the number of effective cells having the second resistance state among the plurality of effective cells SC10 and the number of compensation cells having the first resistance state among the plurality of compensation cells CC10 to the same number in each of the plurality of cell strings ST10. In this case, the number of cells C10 having the first resistance state and the number of cells C10 having the second resistance state in one cell string ST10 may be the same. Accordingly, it is possible to prevent or minimize a change in string resistance of the cell string ST10 according to a change in the resistance states of the plurality of effective cells SC10 in the corresponding cell string ST10.

According to another embodiment, in each of the plurality of cell strings ST10, the number of the plurality of compensation cells CC10 may not be the same as the number of the plurality of effective cells SC10. For example, in each of the plurality of cell strings ST10, the number of the plurality of compensation cells CC10 may be less than the number of the plurality of effective cells SC10. As a specific example, in each of the plurality of cell strings ST10, the number of the plurality of compensation cells CC10 may be about ⅓ of the number of the plurality of effective cells SC10 or more. In each of the cell strings ST10, the string resistance may be controlled or compensated by using a smaller number of compensation cells CC10 than the number of the plurality of effective cells SC10. In this case, the vertical NAND flash type semiconductor device may be configured to adjust the number of effective cells having a first resistance state among the plurality of effective cells SC10 and the number of compensation cells having the second resistance of the plurality of compensation cells CC10 to state of a ratio other than 1:1 in each of the plurality of cell strings ST10. Here, the second resistance state may be an inverse resistance state of the first resistance state.

According to another embodiment, each of the plurality of cells C10 may be a multi-level cell having three or more resistance states instead of the above-described binary cell. In this case, one cell C10 has a resistance state corresponding to ‘0’, a resistance state corresponding to ‘1’, and at least one intermediate resistance state corresponding to an intermediate value(s) between ‘0’ and ‘1’. In this case, the resistance state corresponding to ‘0’ and the resistance state corresponding to ‘1’ may be referred to as mutual inverse resistance state. Also, for example, the resistance state corresponding to ‘⅓’ and the resistance state corresponding to ‘⅔’ may be referred to as mutual inverse resistance state. Furthermore, similarly, the resistance state corresponding to ‘0.1’ and the resistance state corresponding to ‘0.9’ may be referred to as mutual inverse resistance state, and the resistance state corresponding to ‘0.2’ and the resistance state corresponding to ‘0.8’ may be referred to as a mutual inverse resistance state, and a resistance state corresponding to ‘0.3’ and a resistance state corresponding to ‘0.7’ may be referred to as a mutual inverse resistance state. As such, in the present specification, resistance states in which two resistance states are summed to become ‘1’ may be defined as mutual inverse resistance states. In other words, the resistance states which combine two resistance states to correspond to a fully (or substantially fully) programmed (or charged) state may be defined as mutual inverse resistance states. In addition, the term ‘reverse resistance state’ is not necessarily limited to the reverse state and may be interpreted in a broad sense. When each of the cells C10 is the above-described multi-level cell, the vertical NAND flash type semiconductor device may be configured to adjust the number of effective cells having the first resistance state among the plurality of effective cells SC10 and the number of compensation cells having the second resistance state among the plurality of compensation cells CC10 to a predetermined ratio in each of the plurality of cell strings ST10. In embodiments, the predetermined ratio may be obtained by adjusting the number of compensation cells among the plurality of compensation cells CC10 having the second resistance state. Here, the second resistance state may be an inverse resistance state of the first resistance state.

In embodiments, a compensation substring resistance of the compensation cells CC10 of a cell string is adjusted by programming the compensation cells CC10 so that a sum of the compensation substring resistance and an effective substring resistance of the effective cells SC10 is substantially equal to a constant K. In embodiments, the compensation substring resistance may be a sum of the channel resistances of the compensation cells CC10 when a pass voltage is supplied to all the wordlines of the compensation cells CC10, and the effective substring resistance may be a sum of the channel resistances of the effective cells SC10 when a pass voltage is supplied to all the wordlines of the effective cells SC10.

For example, in an embodiment including a vertical NAND flash semiconductor device wherein the cells have only two resistance states, a number NCC1 of compensation cells CC10 having the first resistance state and a number NCC2 of compensation cells CC10 having the second resistance state is determined so that:

NCC1*R1+NCC2*R2=K−NSC1*R1+NSC2*R2 Equation 1

wherein R1 is a resistance value of the first resistance state when the pass voltage is supplied to the respective cell, R2 is a resistance value of the second resistance state when the pass voltage is supplied to the respective cell, NSC1 is the number of effective cells having the first resistance state, and NSC2 is the number of effective cells having the second resistance state.

More generally, in an embodiment including a vertical NAND flash semiconductor device wherein the cells have N resistance states, N greater than two, numbers NCCx of compensation cells CC10 respectively having the x^{th} resistance state, x in 1 . . . N, is determined so that:

$${\sum }_{x = 1}^{N} NCCx * Rx = K - {\sum }_{x = 1}^{N} NSCx * Rx \qquad Equation 2$$

wherein Rx is a resistance value of the x^{th} resistance state when the pass voltage is supplied to the respective cell and NSCx is a number of effective cells having the x^{th} resistance state.

Even more generally, in an embodiment including a vertical NAND flash semiconductor device wherein the effective cells have N resistance states (N greater than or equal to two), and wherein the compensation cells have M resistance states (M greater than or equal to two), numbers NCCx of compensation cells CC10 respectively having the x^{th} resistance state, x in 1 . . . M, is determined so that:

$${\sum }_{x = 1}^{M} NCCx * RCx = K - {\sum }_{y = 1}^{N} NSCy * RSy \qquad Equation 3$$

wherein RCx is a resistance value of the x^{th} resistance state of a compensation cell CC10 when the pass voltage is supplied to that cell, RSy is a resistance value of the y^{th} resistance state of an effective cell CC10 when the pass voltage is supplied to that cell, and NSCy is a number of effective cells having the y^{th} resistance state.

Note that in respective variants of the embodiments characterized by Equations 1, 2, and 3, above, rather than solving the respective equations for the numbers NCCx of compensation cells CC10 so that the left side of the equation is equal to the right side, the equations may be solved so that the left side of the respective equation is within a predetermined tolerance range or a predetermined tolerance percentage of the right side.

In an embodiment of the present invention, the plurality of effective cells SC10 may be synaptic cells that mimic a synapse. In other words, the effective cell group SG1 may be a synaptic device group. In this case, the vertical NAND flash type semiconductor device may be a neuromorphic device. The neuromorphic device may be configured to sum the current values measured in at least two bit lines among the plurality of bit lines BL1, BL2, and BL3 in relation to a data read operation. In other words, when the plurality of effective cells SC10 are used as synaptic devices (cells), the sum of currents flowing through bit lines in the turn-on region may be used to perform operations of the neuromorphic device. Accordingly, when reading the effective cells SC10, the neuromorphic device needs to produce more consistent and accurate measured current values compared to a non-neuromorphic memory device, that is, a memory device which senses a threshold voltage (Vₜₕ).

If the compensation cells CC10 are not used, the string resistance of the corresponding cell string may be changed according to a change in the resistance states of the plurality of effective cells SC10, and as a result, a current value measured for a predetermined selected cell SC10 in the corresponding bit line may be changed. As an example, as the number of programmed effective cells increases among the plurality of effective cells SC10, the string resistance may increase, and a current value measured for a predetermined selected cell SC10 in a corresponding bit line may be reduced. A change in the current value measured in the corresponding bit line according to the change in string resistance may reduce accuracy of weight summation and accuracy of inference, and may deteriorate performance of the neural network.

However, according to the embodiment of the present invention, since the resistance states of the plurality of compensation cells CC10 are controlled according to the resistance states of the plurality of effective cells SC10 in each of the cell strings ST10 by using the plurality of compensation cells CC10, a change in string resistance of a corresponding cell string according to a change in resistance states of the plurality of effective cells SC10 may be controlled or suppressed. Accordingly, even if the resistance states of the plurality of effective cells SC10 are changed, the string resistance of the corresponding cell string may be maintained as being constant or substantially being constant, the accuracy of weight summation and accuracy of inference may be increased, and as a result, performance of the neural network may be improved. That is, in embodiments, when an effective cell in a cell string is read to generate a bit line current having a magnitude that varies according to a value programmed in that effective cell, the effect that the values programmed into the unread effective cells of that cell string have on that bit line current is minimized, and accordingly the accuracy of a computational result produced using that bit line current may be improved. In particular, in embodiments wherein the string resistance of a plurality of cell strings are adjusted as described above, when a first effective cell from a first cell string and a second effective cell from second cell string are both read to produce a computational result, the first and second bit line currents respectively produced by the first and second cell strings will be substantially the same when the values programmed in the first and second effective cells are the same, regardless of the values programmed into the other (unread) effective cells of the first and second cell strings.

The vertical NAND flash type semiconductor device according to an embodiment of the present invention is not limited to the above-described neuromorphic device, and may be used as a device for other purposes. For example, the vertical NAND flash type semiconductor device may also be used as a memory device other than a neuromorphic device. When the plurality of effective cells SC10 are used as memory cells, a relatively large program/erase window may be used, and the string resistance may be changed more significantly according to data stored in the plurality of effective cells SC10. Also, a change in current due to the string resistance may affect the threshold voltage (Vₜₕ). According to an embodiment of the present invention, characteristics and performance of a memory device may be improved by suppressing a change in the string resistance.

According to an embodiment, the number of the plurality of effective cells SC10 in each of the cell strings ST10 of the vertical NAND flash type semiconductor device may be greater than or equal to about 8 and less than or equal to about 200. For example, the number of the plurality of effective cells SC10 in each of the cell strings ST10 may be about 16 to about 100 or about 16 to about 50. In the case of a vertically stacked semiconductor device, data density may be easily increased by increasing the number of stacking layers on a predetermined unit area.

Additionally, the vertical NAND flash type semiconductor device according to the embodiment of the present invention may include a control unit (that is, a control circuit. The vertical NAND flash type semiconductor device may control a change in string resistance of a corresponding cell string according to a change in the resistance states of the plurality of effective cells SC10 by controlling the resistance states of the plurality of compensation cells CC10 according to the resistance states of the plurality of effective cells SC10 in each of the plurality of cell strings ST10, by using the control unit (that is, control circuit).

The control unit may be configured to perform data write, read, and erase operations. The control unit may be configured to write predetermined data to the plurality of effective cells SC10 and to control the resistance states of the plurality of compensation cells CC10 according to the resistance states (i.e., data) of the plurality of effective cells SC10. Since the controlling the resistance states of the plurality of compensation cells CC10 is substantially the same as, or similar to writing predetermined data in the plurality of compensation cells CC10, the resistance states of the plurality of compensation cells CC10 may be easily controlled according to the manner which is the same as (or almost similar to) a method for controlling the resistance states of the plurality of effective cells SC10. The resistance states of the plurality of compensation cells CC10 may be controlled in connection with the resistance states of the plurality of effective cells SC10.

Additionally, the vertical NAND flash type semiconductor device according to the exemplary embodiment may further include at least one switching device connected to each of both ends of each of the plurality of cell strings ST10. In other words, one or more switching devices may be connected to each of both ends of each cell string ST10. The switching device may serve to control selection or access to the cell string ST10. In addition, the vertical NAND flash type semiconductor device according to an embodiment of the present invention may be referred to as a kind of semiconductor device architecture.

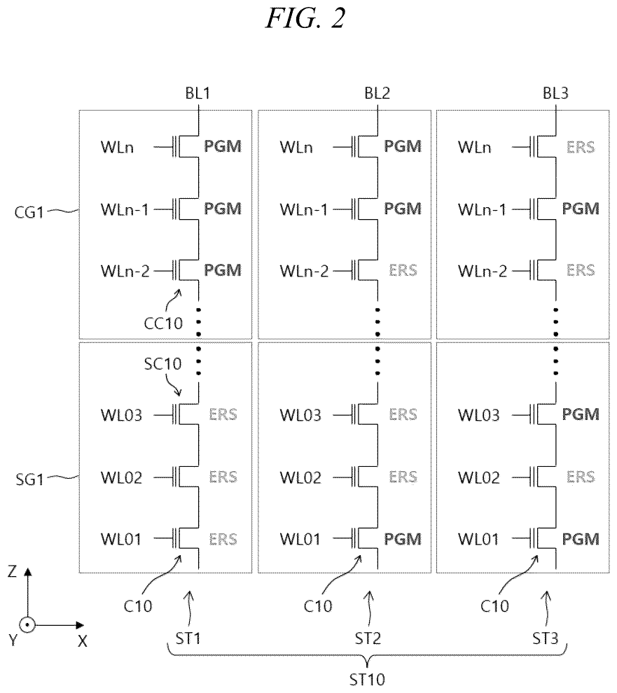

FIG. 2 is a circuit diagram illustrating an example case in which the resistance states of the effective cells SC10 and the resistance states of the compensation cells CC10 in each of the plurality of cell strings ST10 are adjusted in a vertical NAND flash type semiconductor device according to an embodiment of the present invention.

Referring to FIG. 2, the number of the plurality of effective cells SC10 and the number of the plurality of compensation cells CC10 in each cell string ST10 may be the same. In addition, each of the plurality of cells C10 may be a binary cell having a first resistance state and a second resistance state. The first resistance state may be an erased state (indicated by ERS), and the second resistance state may be a programmed state (indicated by PGM). The vertical NAND flash type semiconductor device may be configured to adjust the number of effective cells having the first resistance state ERS among the plurality of effective cells SC10 and the number of compensation cells having the second resistance state PGM among the plurality of compensation cells CC10 to a same number in each of the plurality of cell strings ST10. In addition, the vertical NAND flash type semiconductor device includes may be configured to adjust the number of effective cells having the second resistance state PGM among the plurality of effective cells SC10 and the number of compensation cells having the first resistance state ERS among the plurality of compensation cells CC10 to the same number in each of the plurality of cell strings ST10.

When all of the plurality of effective cells SC10 in the first cell string ST1 have the first resistance state ERS, all of the plurality of compensation cells CC10 may be configured to have the second resistance state PGM. Here, the effective cell SC10 connected to the word line WL02 may be a selected cell.

When one effective cell SC10 among the plurality of effective cells SC10 in the second cell string ST2 has the second resistance state PGM and the remaining effective cells SC10 has the first resistance state ERS, one compensation cell CC10 among the plurality of compensation cells CC10 may be configured to have the first resistance state ERS and the other compensation cells CC10 may be configured to have the second resistance state PGM. Here, the effective cell SC10 connected to the word line WL02 may be a selected cell.

When two effective cells SC10 among the plurality of effective cells SC10 in the third cell string ST3 have the second resistance state PGM and the remaining effective cells SC10 have the first resistance state ERS, two compensation cells CC10 among the plurality of compensation cells CC10 may be configured to have the first resistance state ERS and the remaining compensation cells CC10 may be configured to have the second resistance state PGM. Here, the effective cell SC10 connected to the word line WL02 may be a selected cell.

Accordingly, the number of cells C10 having the first resistance state ERS and the number of cells C10 having the second resistance state PGM may be the same in each cell string ST1, ST2, and ST3. Accordingly, it is possible to prevent or minimize a change in string resistance of the cell string ST1, ST2 or ST3 according to a change in the resistance states of the plurality of effective cells SC10 in the corresponding cell string ST1, ST2, or ST3.

In FIG. 2, a case that the number of the plurality of effective cells SC10 and the number of the plurality of compensation cells CC10 in each cell string ST10 are the same, and each of the plurality of cells C10 is a binary cell having a first resistance state and a second resistance state is illustrated. But, this is exemplary and may be variously changed depending on the case. The number of the plurality of effective cells SC10 and the number of the plurality of compensation cells CC10 in each cell string ST10 may be different from each other. In addition, each of the plurality of cells C10 may be a multi-level cell having three or more resistance states.

In a cell string array of a NAND flash memory, since several cells are connected in series to one cell string, in addition to the threshold voltage shift (Vₜₕ shift) according to the resistance state (e.g., program/erase state) of the read cell, the cell string resistance is changing according to resistance states (e.g., program/erase states) of other cells connected to the string, and a current change occurs accordingly. In particular, since the neural network uses the sum of currents of bit lines, if an undesired current change according to string resistance occurs, the performance of the neural network may be deteriorated. According to the embodiment of the present invention, it is possible to effectively improve and solve these problems.

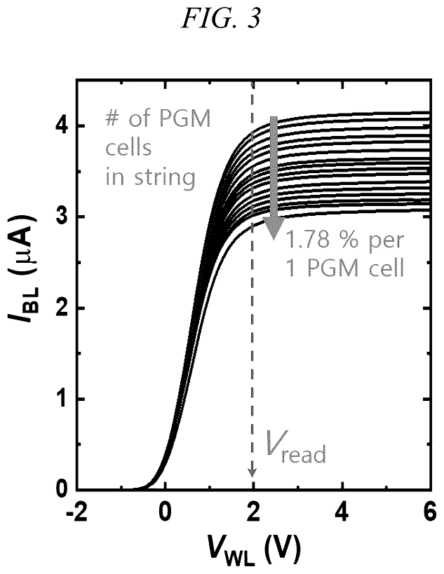

FIG. 3 is a graph illustrating problematic string resistance changes according to a change in resistance states of a plurality of cells for data storage in a vertical NAND flash type semiconductor device of the related art which does not use compensation cells. In this case, the cell string used for measurement included 16 cells connected in series, but did not include any compensation cells. That is, the cell string effectively consisted of only 16 effective cells SC10 without the compensation cell group CG1 in the first cell string ST1 of FIG. 2. The measurement was performed by setting the cell corresponding to the WL01 word line as the selected cell, and successively measuring the current in the corresponding bit line when reading the selected cell after programming the remaining 15 cells one by one. That is, a cell corresponding to the WL01 word line was selected as a selected cell, the cell corresponding to the WL01 word line was successively read after one, two, three, four and so on of the remaining 15 cells were programmed, and for each number of the remaining 15 cells that were programmed, a respective bit line current I_{BL} was measured for a range of word line voltages V_{WL}.

Referring to FIG. 3, it may be confirmed that as the unselected cells connected to the corresponding cell string are programmed one by one, the string resistance increases and the bit line current (I_{BL}) measured for the selected cell in the ON region gradually decreases. In this case, the read voltage (V_{read}) applied to the word line may be about 1.5 to 2.5V, and 2V was used at this time. As the number of programmed unselected cells increased by one, the bit line current (I_{BL}) decreased by about 1.78%. When all 15 unselected cells were programmed, the bit line current (I_{BL}) decreased by about 25% or more. Accordingly, when compensation cells are not used, the string resistance of the corresponding cell string may be relatively significantly changed according to a change in the resistance states of the cells, and as a result, the current value measured in the bit line may be significantly changed. However, according to an embodiment of the present invention, it is possible to suppress or prevent such a problematic change in string resistance. Meanwhile, in FIG. 3, V_{WL} corresponding to the X-axis coordinate of the graph indicates a voltage applied to the word line.

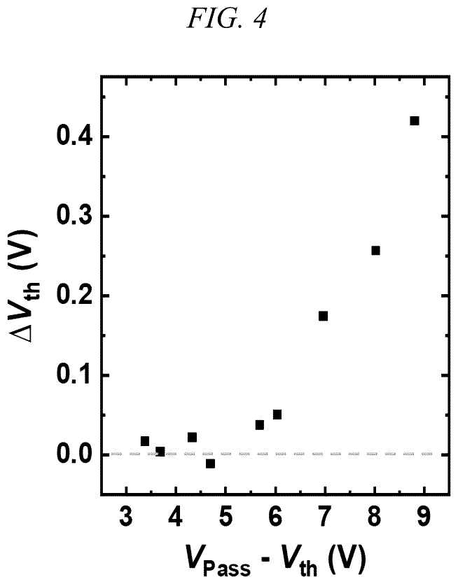

FIG. 4 is a graph illustrating a result obtained by measuring the threshold voltage change amount (ΔVₜₕ) according to the change of the overdrive voltage (Vₚₐₛₛ−Vₜₕ) in reading the cell corresponding to the word line WL01 in the measurement of FIG. 3. Here, Vₚₐₛₛ denotes a pass voltage applied to unselected cells to increase read sensitivity when reading a cell corresponding to the WL01 word line which is a selected cell. Also, Vₜₕ a represents the threshold voltage of the cell.

Referring to FIG. 4, when reading the cell corresponding to the word line WL01, an attempt can be made to reduce the influence of the cells on the string resistance by increasing Vₚₐₛₛ, but in this case, read disturb becomes strong, and data loss may occur. Therefore, it may be difficult to overcome the problem of a change in string resistance by altering Vₚₐₛₛ. In this measurement, when the overdrive voltage (Vₚₐₛₛ−Vₜₕ) was more than 5V, read disturb increased remarkably. Accordingly, the read operation was performed by setting the overdrive voltage to 5V.

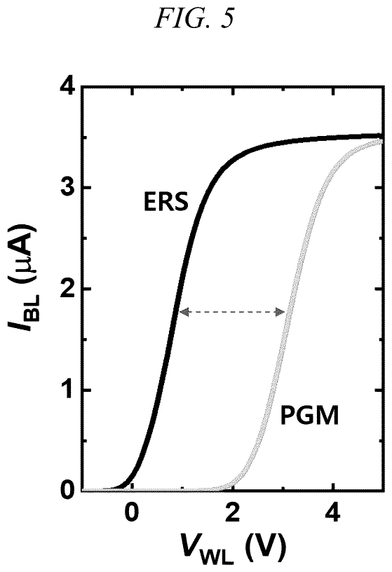

FIG. 5 is a graph illustrating a program/erase window of a cell included in the vertical NAND flash type semiconductor device applied to the measurement of FIG. 3.

Referring to FIG. 5, the voltage difference in the horizontal direction between the I-V curve in the cell-programmed state (PGM), and the I-V curve in the cell-erased state (ERS) may be a program/erase window. In the measurement of FIG. 3, a cell having a program/erase window of about 2V was used. Even if a cell having a window of about 2V is used without using a cell having a relatively large window, the problem as described in FIG. 3 may occur. In addition, if Vu is excessively increased, retention characteristics may be degraded as a result, and thus it may not be desirable to increase Vu above a predetermined level.

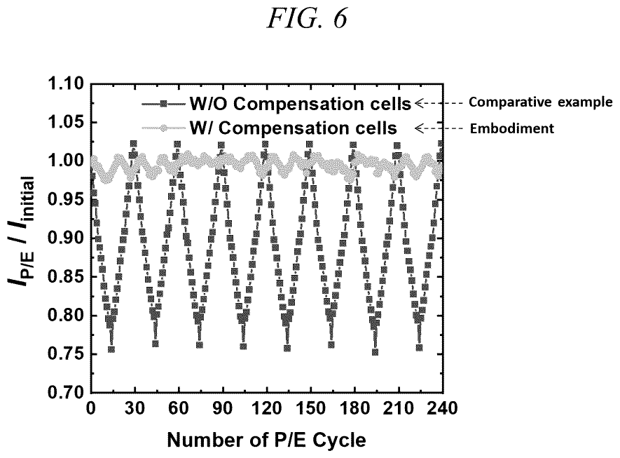

FIG. 6 is a graph illustrating a result obtained by evaluating a change in measurement current over a number of program/erase (P/E) cycles in a vertical NAND flash type semiconductor device according to an embodiment of the present invention and a vertical NAND flash type semiconductor device according to a comparative example.

The vertical NAND flash type semiconductor device according to the embodiment has a structure such as shown in FIG. 2, wherein the number of the plurality of effective cells SC10 included in one cell string was 8, and the number of the plurality of compensation cells CC10 was 8. After setting the effective cell connected to the word line WL01 in the first cell string ST1 as the selection cell, successive read operations were performed on the selected cell while increasing the number of programmed cells in the remaining cells among the plurality of effective cells SC10 one by one, and simultaneously decreasing the number of programmed cells in the plurality of compensation cells CC10 one by one. In addition, after programming all of the remaining cells, a read operation was performed on the selected cell while reducing the number of programmed cells in the remaining cells one by one, and simultaneously increasing the number of programmed cells in the plurality of compensation cells CC10 one by one. This program/erase (P/E) cycle was repeatedly performed. A change of the current was evaluated by comparing the initial current (Iᵢₙᵢₜᵢₐₗ) and the current (I_{P/E}) after each program/erase (P/E). A read current for the read operation was 2V. Both of Iᵢₙᵢₜᵢₐₗ and I_{P/E} are current values measured on the corresponding bit line.

Meanwhile, the vertical NAND flash type semiconductor device according to the comparative example includes 16 cells connected in series to one cell string, but does not include a compensation cell. The cell string may include only 16 effective cells SC10 without the compensation cell group CG1 in the first cell string ST1 of FIG. 2. First of all, a cell corresponding to the WL01 word line was set as a selected cell, and successive read operations were performed on the selected cell while programming the remaining 15 cells one by one. Also, after programming all of the remaining cells, additional successive read operations were performed on the selected cells while decreasing the number of programmed cells in the remaining cells one by one. Such a program/erase (P/E) cycle was repeatedly performed. A change of the current was evaluated by comparing the initial current (Iᵢₙᵢₜᵢₐₗ), and the current (I_{P/E}) after the program/erase (P/E). A read current for the read operation was 2V. Both of Iᵢₙᵢₜᵢₐₗ and I_{P/E} are the current values measured on the corresponding bit line.

Referring to FIG. 6, in a case of the vertical NAND flash type semiconductor device according to the comparative example in which the compensation cell is not used, it may be seen that the measured current for the selected cell is significantly changed as a resistance state of unselected cells (i.e., the remaining cells) is changing one by one. As the number of programmed cells in the unselected cells (i.e., the remaining cells) increases, the measurement current may increase, and as the number of erased cells in the unselected cells (i.e., the remaining cells) increases, the measured current may decrease. The difference between the initial current (Iᵢₙᵢₜᵢₐₗ), and the current (I_{P/E}) after the program/erase (P/E) may be at most about 25% or more. As the number of unit cells connected to one cell string increases, the problem related to a change in string resistance may be further exacerbated.

On the other hand, in a case of the vertical NAND flash type semiconductor device according to the embodiment using the compensation cell, even if the resistance state of unselected cells (i.e., the remaining cells) among the effective cells is changed, it may be confirmed that the measurement current measured for the selected cell here hardly changes and remains substantially constant. This result may be obtained by suppressing a change in resistance of a cell string according to a change in resistance states of the unselected cells (i.e., the remaining cells) by using compensation cells. Accordingly, it is possible to obtain an almost constant measured current value for the same resistance state of the same selected cell regardless of the programmed values of the unselected cells.

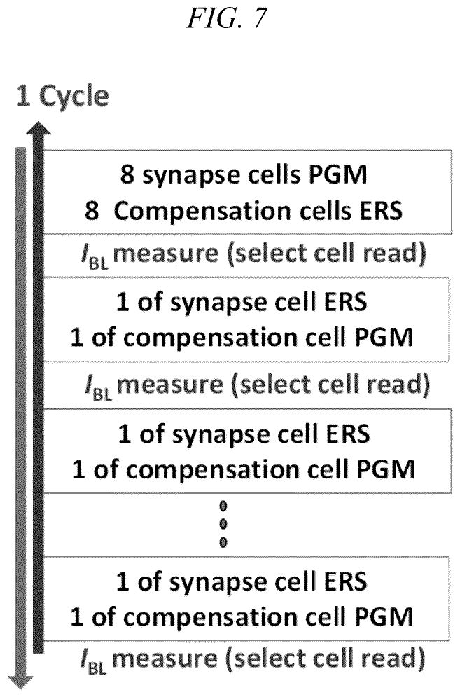

FIG. 7 is a schematic diagram illustrating a program/erase (P/E) cycle and current measurement method which may be applied when evaluating the vertical NAND flash type semiconductor device according to the embodiment described with reference to FIG. 6.

Referring to FIG. 7, the vertical NAND flash type semiconductor device according to the embodiment has a structure as shown in FIG. 2, wherein the number of effective cells included in one cell string was 8, and the number of the plurality of compensation cells was 8. In this case, the plurality of effective cells may be synaptic cells. In an initial state, eight effective cells may be in a programmed state, and eight compensation cells may be in an erased state. In this case, a read operation may be performed on a selected cell among the plurality of effective cells in the cell string. Then, subsequent read operations may be performed on the selected cell after reducing the number of programmed remaining cells (the non-selected cells) among the plurality of effective cells one by one, and accordingly increasing the number of programmed cells in the plurality of compensation cells one by one. Also, after erasing all of the remaining cells, a read operation may be performed on the selected cell while programming the remaining cells one by one, and accordingly reducing the number of programmed cells in the plurality of compensation cells one by one. Such a program/erase (P/E) cycle may be repeatedly performed.

Alternatively, in the initial state, eight effective cells may be in an erased state, and eight compensation cells may be in a programmed state. In this case, successive read operation may be performed on the selected cell after increasing the number of programmed cells in the remaining cells (the non-selected cells) among the plurality of effective cells one by one, and accordingly reducing the number of programmed cells in the plurality of compensation cells one by one. Also, after programming all of the remaining cells, successive read operation may be performed on the selected cell after reducing the number of programmed cells in the remaining cells one by one, and accordingly increasing the number of programmed cells in the plurality of compensation cells one by one. Such a program/erase (P/E) cycle may be repeatedly performed.

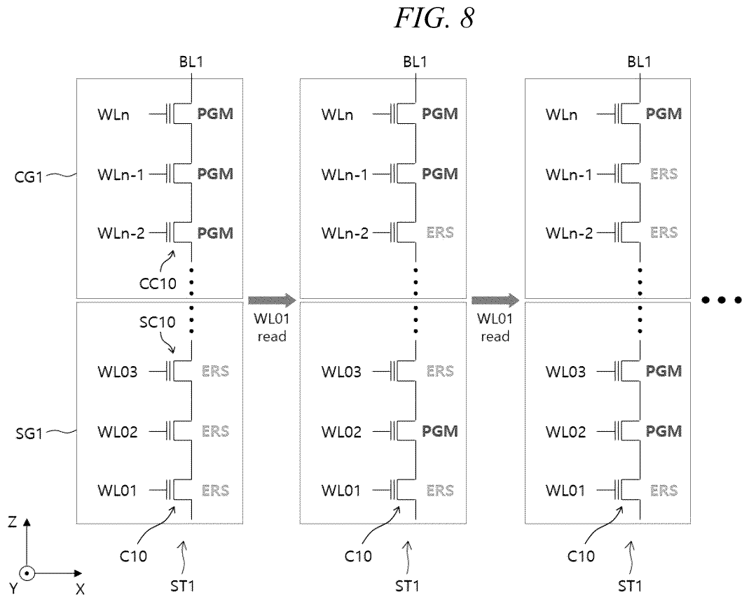

FIG. 8 includes circuit diagrams illustrating a program/erase (P/E) cycle and a current measurement method which may be applied when evaluating the vertical NAND flash type semiconductor device according to the embodiment described with reference to FIG. 6.

Referring to FIG. 8, the vertical NAND flash type semiconductor device according to the embodiment has a structure as shown in FIG. 2, wherein the number of effective cells SC10 included in one cell string ST1 may be eight and the number of the plurality of compensation cells CC10 may be eight. After setting an effective cell connected to the word line WL01 in the cell string ST1 as a selection cell, successive read operations may be performed on the selected cell while increasing the number of programmed cells among the remaining cells (the non-selected cells) among the plurality of effective cells SC10 one by one, and accordingly simultaneously decreasing the number of programmed cells among the plurality of compensation cells CC10 one by one. Subsequently, after programming all of the remaining cells, successive read operation may be performed on the selected cell while decreasing the number of programmed cells among the remaining cells one by one, and accordingly simultaneously increasing the number of programmed cells among the plurality of compensation cells CC10 one by one. Such a program/erase (P/E) cycle may be repeatedly performed.

The method of operating a vertical NAND flash type semiconductor device according to an embodiment of the present invention may include preparing the vertical NAND flash type semiconductor device. The vertical NAND flash type semiconductor device may have the configuration which is same as that described with reference to FIGS. 1 and 2. The vertical NAND flash type semiconductor device may include a plurality of cell strings extending vertically, and each of the plurality of cell strings may include a plurality of cells connected in series in a vertical direction. The plurality of cells in each of the plurality of cell strings may include a plurality of effective cells for data storage, and a plurality of compensation cells for resistance compensation. The method of operating the vertical NAND flash type semiconductor device may include controlling resistance states of the plurality of compensation cells according to resistance states of the plurality of effective cells in one cell string among the plurality of cell strings. A change in string resistance according to a change in the resistance states of the plurality of effective cells in the cell string may be controlled by the controlling the resistance states of the plurality of compensation cells.

All of the features described with reference to FIGS. 1 and 2 may be applied to the method of operating the above-described vertical NAND flash type semiconductor device. Accordingly, each of the plurality of cells may have a plurality of resistance states, and the plurality of resistance states may include a first resistance state and a second resistance state corresponding to an inverse resistance state of the first resistance state. In the controlling the resistance states of the plurality of compensation cells, the number of effective cells having the first resistance state among the plurality of effective cells of the cell string, and number of the compensation cells having the second resistance state among the plurality of compensation cells may be adjusted to a predetermined ratio. Here, the predetermined ratio may be, for example, 1:1, but in some cases, it may be a ratio other than 1:1.

In embodiments, in each of the plurality of cell strings, the number of the plurality of compensation cells may be same as the number of the plurality of effective cells, but in other embodiments the numbers may be different. In the latter case, in each of the plurality of cell strings, the number of the plurality of compensation cells may be less than the number of the plurality of effective cells. For example, in each of the plurality of cell strings, the number of the plurality of compensation cells may be about ⅓ or more of the number of the plurality of effective cells. String resistance may be controlled or compensated by using a number of compensation cells smaller than the number of effective cells in each of the cell strings.

Each of the plurality of cells may be a binary cell having a first resistance state and a second resistance state. However, in some cases, each of the plurality of cells may be a multi-level cell having three or more resistance states instead of the binary cell.

When the number of the plurality of compensation cells and the number of the plurality of effective cells are same in each of the plurality of cell strings, and each of the plurality of cells is a binary cell having a first resistance state and a second resistance state, the method of operating a vertical NAND flash type semiconductor device may be configured to adjust the number of effective cells having the first resistance state among the plurality of effective cells and the number of compensation cells having the second resistance state among the plurality of compensation cells of the cell string may be adjusted to the same ratio (i.e., equalize) in the controlling the resistance states of the plurality of compensation cells. In addition, in the controlling the resistance states of the plurality of compensation cells, the number of effective cells having the second resistance state among the plurality of effective cells of the cell string and the number of compensation cells having the first resistance state among the plurality of compensation cells of the cell string may be adjusted to the same ratio (i.e., equalized).

The plurality of effective cells may be synaptic cells which mimic synapses. In this case, the vertical NAND flash type semiconductor device may be a neuromorphic device. The neuromorphic device may be configured to sum respective current values measured in at least two bit lines among a plurality of bit lines in connection with a data read operation. In other words, when the plurality of effective cells are used as synaptic devices (cells), the sum of currents respectively flowing through the bit lines in a turn-on region may be used. Accordingly, the neuromorphic device needs to more accurately adjust measured current values as compared to a non-neuromorphic memory device. According to an embodiment of the present invention, even if the resistance states of the plurality of effective cells are changed, the string resistance of the corresponding cell string may be maintained as being constant or substantially constant, and as a result the accuracy of weight summation and inference accuracy may be increased. As a result, the performance of the neural network may be improved. However, the vertical NAND flash type semiconductor device according to an embodiment of the present invention is not limited to the above-described neuromorphic device, and may be used as a device for other purposes. For example, the vertical NAND flash type semiconductor device may be used as a memory device other than a neuromorphic device.

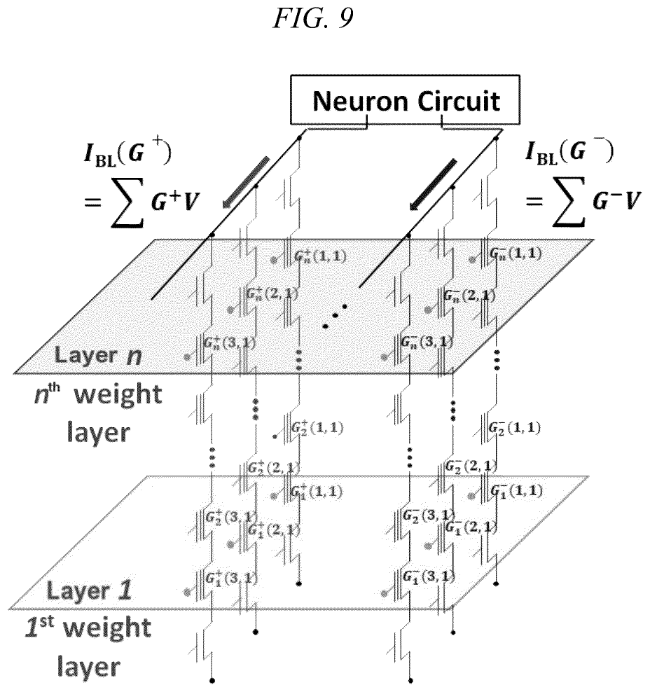

FIG. 9 is a circuit diagram schematically illustrating a neuromorphic device using a vertical NAND flash type semiconductor device.

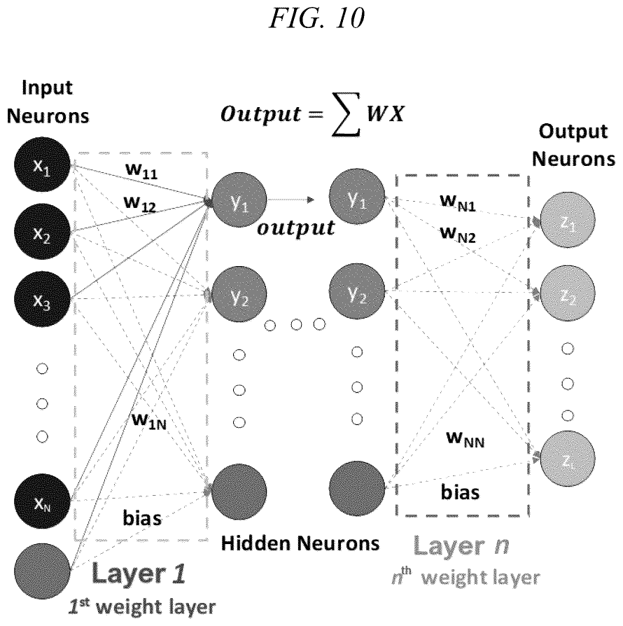

FIG. 10 is a conceptual diagram illustrating a neural network using a vertical NAND flash type semiconductor device.

Referring to FIG. 9 and FIG. 10, a correlation between a neural network and a hardware-based neuromorphic system (device) may be given as in Equation 4 below.

O=ΣWX<⇔I=ΣGV Equation 4

In Equation 4, O, W, and X are an output, weights, and inputs, respectively, and accordingly Σ(WX) is a weighted sum of the inputs. Also, I, G, and V are a sum of bit line currents I_{BL}, conductances of cells, and input voltages corresponding to word line voltages, respectively, and accordingly Σ(GV) corresponds to a weighted sum of the conductances of the cell. According to the circuit rules, I is provided which is the weighted sum of the binary neural network (BNN) by multiplying V by G. In the proposed synaptic architecture, the V-NAND cell of the nth layer may correspond to the nth synaptic layer. During an inference process, a read bias (V_{read}) may be applied to selected synaptic cells, and a pass bias (Vₚₐₛₛ) may be applied to the cells which are not selected to pass a current through the synaptic string. The current generated on the bit lines may then be summed.

The vertical NAND flash type semiconductor device according to embodiments of the present invention may be applied to the neuromorphic device (system) shown in FIG. 9. In embodiments, the accuracy of weight summing and the accuracy of inference may be increased, and consequently, the performance of the neural network may be improved.

According to the embodiments of the present invention described above, it is possible to implement a vertical NAND flash type semiconductor device capable of effectively controlling a change in the resistance of a cell string according to a change in the resistance states of the cells. In particular, according to embodiments of the present invention, in applying the vertical NAND flash structure to a neuromorphic device/system, it is possible to implement a vertical NAND flash type semiconductor device capable of increasing the accuracy of calculation and inference, and improving the performance of a neural network by controlling a change in resistance of a cell string according to a change in resistance states of a plurality of cells connected to that cell string. However, the field of application of the vertical NAND flash type semiconductor device according to the embodiments of the present invention is not limited to the neuromorphic device, and may be applied to devices in other fields.

In the present specification, preferred embodiments of the present invention have been disclosed, and although specific terms are used, these are only used in a general sense to easily describe the technical content of the present invention and to help the understanding of the present invention, and are not used to limit the scope of the present invention. It will be apparent to those having common knowledge in the related art to which the present invention pertains that other modifications based on the technical spirit of the present invention may be implemented in addition to the embodiments disclosed herein. Those having common knowledge in the related art will understand that various substitutions, changes and modifications may be made without departing from the technological concepts of the present invention in connection with vertical NAND flash type semiconductor devices and operating methods thereof according to the embodiments described with reference to FIGS. 1 to 10. As a specific example, when the technology and idea according to an embodiment of the present invention are applied to a memory device, it may be possible to appropriately adjust/control the resistance of the cell string by using one to several compensation cells in one cell string. Therefore, the scope of the invention should not be determined by the described embodiments, but should be determined by the technological concepts described in the claims.

### EXPLANATION OF SYMBOLS

### Explanation of Symbols for the Main Parts of the Drawing

BL1˜BL3: bit line C10: cell
CC10: compensation cell CG1: compensation cell group
SC10: effective cell SG1: effective cell group
ST1˜ST3: cell string ST10: cell string
WL01˜WLn: word line

What is claimed is:

1. A vertical NAND flash type semiconductor device comprising:
a plurality of cell strings extending vertically, each comprising a plurality of cells connected in series vertically, the plurality of cells in each of the plurality of cell strings including a plurality of effective cells and a plurality of compensation cells, and
wherein the vertical NAND flash type semiconductor device is configured to control a change in a string resistance of a cell string by controlling resistance states of the plurality of compensation cells according to resistance states of the plurality of effective cells in each of the plurality of cell strings.

2. The vertical NAND flash type semiconductor device of claim 1, wherein each of the plurality of cells has a plurality of resistance states, and the plurality of resistance states include a first resistance state and a second resistance state corresponding to an inverse resistance state of the first resistance state, and
wherein the vertical NAND flash type semiconductor device is configured to adjust a number of effective cells having the first resistance state among the plurality of effective cells and a number of compensation cells having the second resistance state among the plurality of compensation cells to a predetermined ratio in each of the plurality of cell strings.

3. The vertical NAND flash type semiconductor device of claim 2, wherein the predetermined ratio is 1:1.

4. The vertical NAND flash type semiconductor device of claim 1, wherein a number of the plurality of compensation cells in each of the plurality of cell strings is one-third or more of a number of the plurality of effective cells in each of the plurality of cell strings.

5. The vertical NAND flash type semiconductor device of claim 1, wherein a number of the plurality of compensation cells in each of the plurality of cell strings is equal to a number of the plurality of effective cells in each of the plurality of cell strings.

6. The vertical NAND flash type semiconductor device of claim 1, wherein each of the plurality of cells is a binary cell having a first resistance state and a second resistance state.

7. The vertical NAND flash type semiconductor device of claim 6, wherein a number of the plurality of compensation cells in each of the plurality of cell strings is equal to a number of the plurality of effective cells, and
wherein the vertical NAND flash type semiconductor device is configured to equalize a number of effective cells having the first resistance state among the plurality of effective cells and a number of compensation cells having the second resistance state among the plurality of compensation cells in each of the plurality of cell strings.

8. The vertical NAND flash type semiconductor device of claim 1, wherein each of the plurality of cells has a multi-level cell having three or more resistance states.

9. The vertical NAND flash type semiconductor device of claim 1, further comprising a plurality of bit lines respectively connected to the plurality of cell strings are provided, and
wherein the vertical NAND flash type semiconductor device is configured to sum current values measured in at least two bit lines among the plurality of bit lines.

10. The vertical NAND flash type semiconductor device of claim 1, wherein the plurality of effective cells are synaptic cells mimicking a synapse, and the vertical NAND flash type semiconductor device is a neuromorphic device.

11. The vertical NAND flash type semiconductor device of claim 1, wherein controlling the change in the string resistance of the cell string comprises controlling respective values of the plurality of compensation cells in the cell string so that a sum of the resistances of the plurality of cells of the cell string when a pass voltage is applied to gates of each of the plurality of cells of the cell string is substantially equal to a predetermined constant.

12. A method of operating a semiconductor device including vertical NAND flash, the method comprising:
partitioning each of a plurality of cells in a plurality of cell strings of the vertical NAND flash into a plurality of effective cells and a plurality of compensation cells; and
controlling a change in string resistance of a cell string of the plurality of cell strings by controlling resistance states of the plurality of compensation cells of the cell string according to resistance states of the plurality of effective cells of the cell string.

13. The method of claim 12,
wherein each of the plurality of cells has a plurality of resistance states, and the plurality of resistance states include a first resistance state and a second resistance state corresponding to an inverse resistance state of the first resistance state, and
wherein controlling the change in string resistance of the cell string comprises adjusting a number of effective cells having the first resistance state among the plurality of effective cells of the cell string and a number of compensation cells having the second resistance state among the plurality of compensation cells of the cell string to a predetermined ratio.

14. The method of claim 13, wherein the predetermined ratio is 1:1.

15. The method claim 12, wherein a number of the plurality of compensation cells in each of the plurality of cell strings is equal to a number of the plurality of effective cells in each of the plurality of cell strings.

16. The method of claim 15, wherein each of the plurality of cells is a binary cell having a first resistance state and a second resistance state, and
wherein controlling the change in string resistance of the cell string comprises equalizing a number of effective cells having the first resistance state among the plurality of effective cells of the cell string and a number of compensation cells having the second resistance state among the plurality of compensation cells of the cell strings.

17. The method of claim 12, wherein the plurality of effective cells are synaptic cells mimicking a synapse, and the vertical NAND flash type semiconductor device is a neuromorphic device.

18. The method claim 12, wherein controlling the change in the string resistance of the cell string comprises controlling respective values of the plurality of compensation cells in the cell string so that a sum of the resistances of the plurality of cells of the cell string when a pass voltage is applied to gates of each of the plurality of cells of the cell string is substantially equal to a predetermined constant.
